(19) United States
(12) Patent Application Publication
(10) Pub. No.: US 2008/0061401 A1
(43) Pub. Date: Mar. 13, 2008

(54) Modified transistor

(76) Inventor: Isaiah Watas Cox, Baltimore, MD (US)

Correspondence Address: BOREALIS TECHNICAL LIMITED, 23545 NW SKYLINE BLVD, NORTH PLAINS, OR, 97133-9204, US

(21) Appl. No.: 11/900,790

(22) Filed: Sep. 12, 2007

(30) Foreign Application Priority Data
Sep. 12, 2006 (GB) GB0617879.2

(51) Int. Cl. H01L 29/735

(52) U.S. Cl. 257/586; 257/E29.187

(57) ABSTRACT

A bipolar-junction transistor is disclosed comprising a first layer, a second layer, and a third layer, the surfaces of the layers modified for more precise control of electron function. The surfaces are modified to have a periodically repeating structure of indents where the indentations are of dimensions so as to create de Broglie wave interference, leading to a change in electron work function.

### CROSS-REFERENCE TO RELATED APPLICATIONS

This application claims the benefit of U.K. Patent Application No. GB0617879.2, filed Sep. 12, 2006, said document incorporated herein in its entirety by reference.

### BACKGROUND OF THE INVENTION

The present invention relates to transistors and more specifically to a modified bipolar-junction transistors. The invention also relates to power amplifiers.

Typically, the portion of the amplifier that actually magnifies the input signal to yield the amplified signal consists of one or more bipolar junction transistors or MOSFET's (metal oxide field effect transistor).

A bipolar junction transistor is comprised of three semiconductor layers, either structured as an N-type semiconductor between two layers of P-type semiconductors, or more typically as a P-type semiconductor disposed between two N-type semiconductors. In both cases, the middle layer functions as the base and the outer layers function as the emitter and collector. The input circuit appears between the base and the emitter and the output circuit is shared by the emitter and the collector. A small input current acts like a switch and allows a larger current to flow through the output circuit.

Electronic amplifiers increase the amplitude of an input signal by drawing power from a power supply and controlling it to match the shape of the input signal, albeit with a larger amplitude. Ideally, the only difference between the input signal and the output signal would be the strength of the signal, with the output an enlarged replica of the input. However, as a matter of course, the process of amplification introduces distortion and unwanted noise into the signal, and some degree of energy is lost as heat. Generally, as efficiency increases the distortion increases and vice versa. To protect electronic equipment, heat sinks and often forced-air cooling devices are necessary, in addition to a variety of additional devices and features such as clipping indicators, thermal overload shutdown, and over-current protectors. Examples of such devices can be found in the art, such as a thermal overload protection system providing supply voltage reduction in discrete steps at predetermined temperature thresholds as disclosed in U.S. Pat. No. 5,939,872 or the amplifier clipping distortion indicator with adjustable supply dependence disclosed in U.S. Pat. No. 5,430,409.

U.S. Pat. Nos. 6,281,514, 6,495,843, and 6,531,703 disclose methods for promoting the passage of electrons at or through a potential barrier comprising providing a potential barrier having a geometrical shape for causing de Broglie interference between electrons. In another embodiment, the invention provides an electron-emitting surface having a series of indents. The depth of the indents is chosen so that the probability wave of the electron reflected from the bottom of the indent interferes destructively with the probability wave of the electron reflected from the surface. This results in the increase of tunneling through the potential barrier. In further embodiments, the invention provides vacuum diode devices, including a vacuum diode heat pump, a thermionic converter and a photoelectric converter, in which either or both of the electrodes in these devices utilize said electron-emitting surface. In yet further embodiments, devices are provided in which the separation of the surfaces in such devices is controlled by piezo-electric positioning elements. A further embodiment provides a method for making an electron-emitting surface having a series of indents.

U.S. Pat. No. 6,680,214 and U.S. Patent App. Pub. No. 2004/0206881 disclose methods for the induction of a suitable band gap and electron emissive properties into a substance, in which the substrate is provided with a surface structure corresponding to the interference of electron waves. Lithographic or similar techniques are used, either directly onto a metal mounted on the substrate, or onto a mold which then is used to impress the metal. In a preferred embodiment, a trench or series of nano-sized trenches are formed in the metal.

U.S. Pat. No. 6,117,344 discloses methods for fabricating nano-structured surfaces having geometries in which the passage of electrons through a potential barrier is enhanced. The methods use combinations of electron beam lithography, lift-off, and rolling, imprinting or stamping processes.

WO9964642 discloses a method for fabricating nanostructures directly in a material film, preferably a metal film, deposited on a substrate. In a preferred embodiment a mold or stamp having a surface which is the topological opposite of the nanostructure to be created is pressed into a heated metal coated on a substrate. The film is cooled and the mold is removed. In another embodiment, the thin layer of metal remaining attached to the substrate is removed by bombardment with a charged particle beam.

WO03083177 teaches that a metal surface can be modified with patterned indents to increase the Fermi energy level inside the metal, leading to decrease in electron work function. This effect would exist in any quantum system comprising fermions inside a potential energy box.

WO04040617 offers a method which blocks movement of low energy electrons through a thermoelectric material. This is achieved using a filter which is more transparent to high energy electrons than to low energy ones. A tunnel barrier on the path of the electrons is used as filter. The filter works on the basis of the wave properties of the electrons. The geometry of the tunnel barrier is such that the barrier becomes transparent for electrons having certain de Broglie wavelength. If the geometry of the barrier is such that its transparency wavelength matches the wavelength of high energy electrons it will be transparent for high energy electrons and will block low energy ones by means of tunnel barrier.

Definition: “Matching” surface features of two facing surfaces of electrodes means that where one has an indentation, the other has a protrusion and vice versa. Thus, the two surfaces are substantially equidistant from each other throughout their operating range.

### BRIEF SUMMARY OF THE INVENTION

The present invention is a bipolar-junction transistor comprising a first layer, a second layer, and a third layer, characterized by a surface of one or more of the layers having a periodically repeating structure having one or more indents of a depth approximately 5 to 20 times a roughness of said surface and a width of approximately 5 to 15 times said depth.

In a first embodiment the first layer and the third layer are comprised of p-type semiconductor material and the second layer is comprised of n-type semiconductor material.

In a second embodiment the first layer and the third layer are comprised of n-type semiconductor material and the second layer is comprised of p-type semiconductor material.

In a third embodiment the present invention contemplates a power supply having an input stage and an output stage, in which the output stage is comprised of one or more transistors having electrodes modified as described above for more precise control of electron function.

One advantage of the present invention is greater efficiency in converting energy from a voltage source into output energy useful for driving speakers. Consequently, less power is consumed in comparison to amplifiers with similar power output. Furthermore, the high efficiency leads to less heat production and thus permits the use of a smaller heat sink or none at all.

Another advantage of the present invention is a reduction of thermal sensitivity due to the predetermined properties of the modified material, thereby decreasing the probability of permanent damage to the amplifier due to junction breakdown. This leads to a further advantage of greater flexibility and a broader temperature range for amplifier applications.

An even further advantage of the present invention is a broader range of materials for use in amplifier transistors, having their surface structures modified to alter the material's chemical and electrical properties. This introduces a further advantage of lower production cost.

Further objects and advantages will become apparent by referring to the appended drawings and detailed descriptions.

### BRIEF DESCRIPTION OF THE SEVERAL VIEWS OF THE DRAWING

For a more complete explanation of the present invention and the technical advantages thereof, reference is now made to the following description and the accompanying drawing in which:

FIG. 1 shows, in schematic form, a diagram of a modified transistor electrode with a periodic repeating structure; and

FIG. 2 is a schematic diagram of a bipolar junction transistor having modified surfaces.

### DETAILED DESCRIPTION OF THE INVENTION

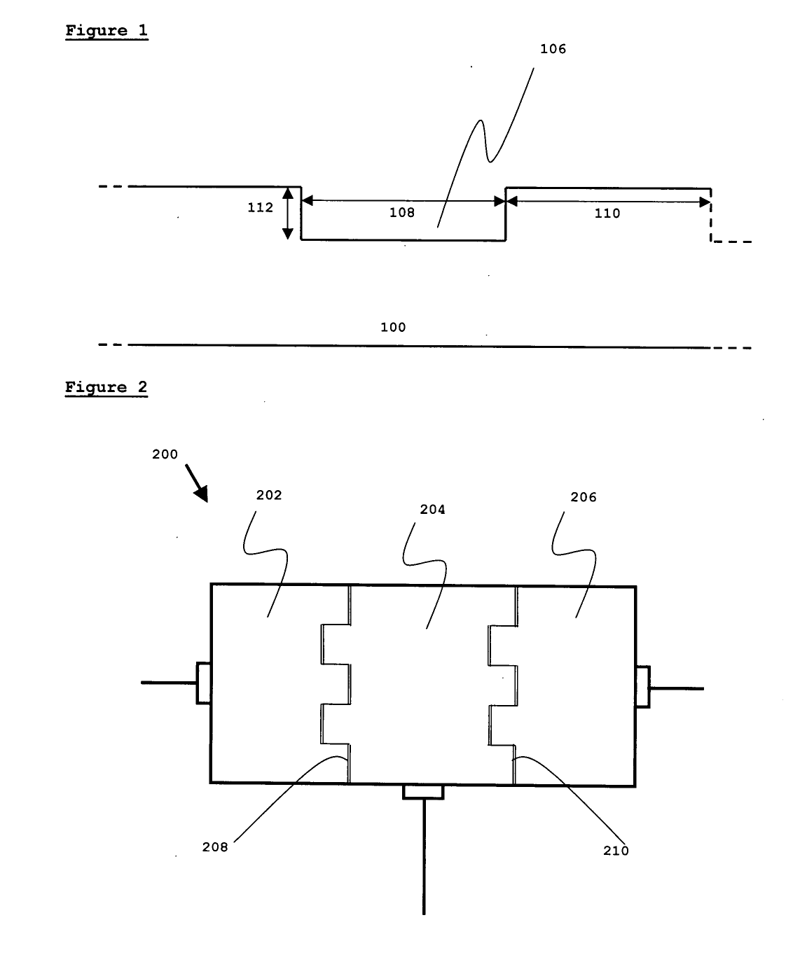

Embodiments of the present invention and their technical advantages may be better understood by referring to FIG. 1, which shows a magnified view of electrode 100. Electrode 100 is one of three semiconductor layers that comprise a bipolar junction transistor for use in an amplifying unit. Electrode 100 has an indent 106 on one surface. Whilst the structure shown in FIG. 1 is a single indented region, this should not be considered to limit the scope of the invention, and dotted lines have been drawn to indicate that in further embodiments the structure shown may be extended in one or both directions to form features on the surface of the electrode that have a repeating or periodic nature. Indent 106 has a width 108 and a depth 112 and the separation between the indents is 110. Preferably distances 108 and 110 are substantially equal. Preferably distance 108 is of the order of 2 μm or less. Experimental observations using a Kelvin probe indicate that the magnitude of a reduction in an apparent work function increases as distance 112 is reduced. Utilization of e-beam lithography to create structures of the kind shown in FIG. 1 may allow indents to be formed in which distance 108 is 200 nm or less. Distance 112 is of the order of 20 nm or less, and is preferably of the order of 5 nm.

The configuration of the surface may resemble a corrugated pattern of squared-off, “u”-shaped ridges and/or valleys. Alternatively, the pattern may be a regular pattern of rectangular “plateaus” or “holes,” where the pattern resembles a checkerboard. The walls of said indents should be substantially perpendicular to one another, and the edges of the indents should be substantially sharp. The surface configuration comprises a substantially plane slab of a material having on one surface one or more indents of a depth approximately 5 to 20 times a roughness of said surface and a width approximately 5 to 15 times said depth. Typically, the depth of the indents is ≧λ/2, wherein λ is the de Broglie wavelength, and the depth is greater than the surface roughness of the metal surface. Typically, the width of the indents is >>λ wherein λ is the de Broglie wavelength. Typically, the thickness of the slab is a multiple of the depth, preferably between 5 and 15 times said depth, and preferably in the range of 15 to 75 nm. Further, one of ordinary skill in the art will recognize that other configurations are possible that may produce the desired interference of wave functions. The surface configuration may be achieved using conventional approaches known in the art, including without limitation lithography and e-beam milling.

The electrodes are modified by the etching of patterned indents onto their surfaces, where the indentations are of dimensions so as to enhance tunneling of electrons between electrodes. This increases the Fermi level inside the material and leads to a reduction in electron work function.

FIG. 2 shows a modified simple bipolar-junction transistor 200 for use in an amplifying unit. Transistor 200 comprises a base material 204 sandwiched between an emitter material 202 and a collector material 206. One or more of materials 202, 204, and 206 have one or more modified surfaces having the geometric structure shown in FIG. 1 such that they are given predefined properties. Materials 202, 204, and 206 are positioned facing one another with surfaces matching and sharing a thin common region, such that when a positive voltage is applied to the base 204 (base-emitter junction 208) the balance between the electrons, the holes, and the depletion zone is disturbed, thus allowing thermally excited electrons to diffuse from the emitter 202 to the base 204 and then to be swept over the base-collector junction 210 by the electric field of junction 210. The dimensions of the repeating structure are such that it leads to a change in work function of junctions 208 and 210, and consequently to the built-in potential of the junction. This leads to a change in the opening voltage and the breakdown voltage of the junction, resulting in a junction with controllable properties.

In a preferred embodiment, base 204 comprises a p-type material and is sandwiched an emitter 202 and collector 206 comprised of n-type materials. In a further embodiment, 204 comprises an n-type material, and materials 202 and 204 comprise of p-type semiconductor material.

Although FIG. 2 shows semiconductor materials 202, 204, and 206 having indented surfaces in contact with one another, that is just one of many possible configurations within the scope of this invention. In an alternative embodiment, semiconductor materials may be positioned such that their planar surfaces are in contact with one another. In a further embodiment, of the junctions 208 and 210, one junction is configured such that its constituent two materials have their indented surfaces contacting each other while the second junction is configured to have the planar surfaces of its constituent two materials in contact with one another.

A further embodiment of the present invention contemplates a power supply having an input stage and an output stage, in which the output stage is comprised of one or more transistors having modified electrodes for more precise control of electron function as described above.

It is obvious that improved materials for use in an amplifier are necessary to provide high efficiency, lower power consumption, less heat production, and less thermal sensitivity, and to ensure sufficient gain, all while maintaining a compact size and a relatively low cost. One advantage of the present invention is greater efficiency in converting energy from a voltage source into output energy useful for driving speakers. Consequently, less power is consumed in comparison to amplifiers with similar power output. Furthermore, the high efficiency leads to less heat production and thus permits the use of a smaller heat sink or none at all.

These modifications may be used and manipulated as disclosed in prior art and the above such that amplifying transistor 200 may be constructed with a broader range of materials to beneficial effect and to have broader applications. Amplifying transistor 200 may also be more efficient and thereby not produce as much heat as its prior art during operation.

1. A bipolar-junction transistor comprising a first layer, a second layer, and a third layer, characterized by a surface of one or more of said layers having a periodically repeating structure having one or more indents of a depth approximately 5 to 20 times a roughness of said surface and a width of approximately 5 to 15 times said depth.

2. The transistor of claim 1, wherein walls of said indents are substantially perpendicular to one another.

3. The transistor of claim 1, wherein edges of said indents are substantially sharp.

4. The transistor of claim 1, wherein said depth is ≧λ/4, wherein λ is the de Broglie wavelength.

5. The transistor of claim 1, wherein said depth approximately 5 nm.

6. The transistor of claim 1, wherein said width >>λ, wherein λ is the de Broglie wavelength.

7. The transistor of claim 1, wherein said width is less than approximately 100 nm.

8. The transistor of claim 1, wherein said first layer and said third layer are comprised of p-type semiconductor material and said second layer is comprised of n-type semiconductor material.

9. The transistor of claim 1, wherein said first layer and said third layer are comprised of n-type semiconductor material and said second layer is comprised of p-type semiconductor material.

10. The transistor of claim 1, wherein the work function of said layers is substantially lower than an transistor with layers comprised of materials that do not comprise said periodically repeating structure.
